(19) United States
(12) Patent Application Publication
(10) Pub. No.: US 2011/0089399 A1
(43) Pub. Date: Apr. 21, 2011

(54) LIGHT EMITTING DEVICE WITH A STAIR QUANTUM WELL STRUCTURE

(75) Inventors: Arpan Chakraborty, Goleta, CA (US); You-Da Lin, Goleta, CA (US); Shuji Nakamura, Santa Barbara, CA (US); Steven P. DenBaars, Goleta, CA (US)

(73) Assignee: THE REGENTS OF THE UNIVERSITY OF CALIFORNIA, Oakland, CA (US)

(21) Appl. No.: 12/901,838

(22) Filed: Oct. 11, 2010

Related U.S. Application Data
(60) Provisional application No. 61/250,391, filed on Oct. 9, 2009.

(51) Int. Cl. H01L 33/04; H01L 33/30

(52) U.S. Cl. 257/13; 438/47; 257/E33.008; 257/E33.027

(57) ABSTRACT

A light emitting device with a stair quantum well structure in an active region. The stair quantum well structure may include a primary well and a single step or multiple steps. The light emitting device may be a nonpolar, semipolar or polar (Al,Ga,In)N based light emitting device. The stair quantum structure improves the radiative efficiency of the light emitting device.

### CROSS-REFERENCE TO RELATED APPLICATIONS

This application claims the benefit under 35 U.S.C. Section 119(e) of co-pending and commonly assigned U.S. Provisional Patent Application Ser. No. 61/250,391, filed on Oct. 9, 2009, by Arpan Chakraborty, You-Da Lin, Shuji Nakamura, and Steven P. DenBaars, entitled “LIGHT EMITTING DEVICE WITH STAIR QUANTUM WELL” attorney's docket number 30794.321-US-P1 (2009-796-1), which application is incorporated by reference herein.

This application is related to co-pending and commonly-assigned U.S. Provisional Patent Application Ser. No. 61/258,158, filed on Nov. 4, 2009, by You-Da Lin, Arpan Chakraborty, Shuji Nakamura, and Steven P. DenBaars, entitled “LIGHT EMITTING DEVICE WITH COUPLED QUANTUM WELLS,” attorney's docket number 30794.339-US-P1 (2010-274-1), which application is incorporated by reference herein.

### STATEMENT REGARDING FEDERALLY SPONSORED RESEARCH AND DEVELOPMENT

This invention was made with Government support under Grant No. FA8718-08-C-0005 awarded by DARPA-VIGIL. The Government has certain rights in this invention.

### BACKGROUND OF THE INVENTION

1. Field of the Invention

This invention relates to a light-emitting device with a stair quantum well structure.

2. Description of the Related Art

A quantum well is a potential well that confines particles, which were originally free to move in three dimensions, to two dimensions, forcing them to occupy a planar region. Quantum wells are formed of semiconductor materials by having a quantum well layer with a lower band-gap sandwiched between two barrier layers with a higher or wider bandgap.

A quantum well structure can be illustrated by a graph of its potential energy function, which is the potential energy profile (eV) as a function of position, distance, or thickness (x). As described in more detail below, in such a graph, a horizontal line in the energy diagram indicates no change in the composition of the quantum well structure, a vertical line in the energy diagram indicates a discrete or abrupt change in the composition of the quantum well structure, and a sloping line in the energy diagram indicates a graded change in the composition of the quantum well structure.

With this in mind, three basic quantum well structures used in (Al,Ga,In)N light emitting devices can be described using such graphs:

1. FIG. 1 schematically illustrates a square quantum well structure, by means of a graph of the potential energy function for the structure. In FIG. 1, the vertical lines in the energy diagram on both the left and right sides of the quantum well 100 indicate that there are abrupt changes in composition at the interfaces between the quantum well 100 and the first and second barrier layers 102, 104, respectively.

2. FIG. 2(a) and FIG. 2(b) schematically illustrate a triangular quantum well structure, by means of graphs of the potential energy function. In FIG. 2(a), the sloping line in the energy diagram on the left side of the quantum well 200 indicates that there is a graded interface between the quantum well 200 and the first barrier layer 202, while the vertical line in the energy diagram on the right side of the quantum well 200 indicates that there is an abrupt interface between the quantum well 200 and the second barrier layer 204. Conversely, in FIG. 2(b), the sloping line in the energy diagram on the right side of the quantum well 200 indicates that there is a graded interface between the quantum well 200 and the second barrier layer 204, while the vertical line in the energy diagram on the left side of the quantum well 200 indicates that there is an abrupt interface between the quantum well 200 and the first barrier layer 202.

3. FIG. 3(a) and FIG. 3(b) schematically illustrate a quantum well structure that combines 1 and 2 above. In FIGS. 3(a) and 3(b), the quantum well 300 has a sloping line in the energy diagram, which indicates that the quantum well 300 itself has a graded composition, while the interfaces with the barrier layers 302, 304 have vertical lines in the energy diagram, which indicates an abrupt change in composition at the interface between the quantum well 300 and the barrier layers 302, 304.

The problem with these structures, however, is that, due to the difference in material properties, for example, lattice mismatch, coefficient of thermal expansion (CTE) mismatch, etc., extended defects such as misfit dislocations are created at the well-barrier interface as a strain/stress relaxation mechanism. This effect is more dominant in nonpolar and semipolar III-nitrides because of in-plane anisotropy of the lattice (as shown in the micrograph of FIG. 4). The defects act as a non-radiative recombination center, resulting in a lowering of internal quantum efficiency (IQE) and adversely affecting device reliability.

Furthermore, it is difficult to grow thick InGaN wells of high In composition, which are required for green light emitting quantum wells, because of strain. Thicker wells are desired for long wavelength emission because of reduced quantum confinement, resulting in longer wavelength emission for a particular In composition.

Thus, there is a need in the art for improved quantum well designs. The present invention satisfies this need.

### SUMMARY OF THE INVENTION

To overcome the limitations in the prior art described above, and to overcome other limitations that will become apparent upon reading and understanding the present specification, the present invention describes a stair quantum well design in an active region of a light emitting device. This invention demonstrates the advantages of stair quantum wells to improve the radiative efficiency of light emitting devices. In particular, this invention implements the concept of stair quantum wells in nonpolar, semipolar or polar (Al,Ga,In)N based light emitting devices, wherein the stair quantum wells may include a primary well and a single step or multiple steps.

### BRIEF DESCRIPTION OF THE DRAWINGS

Referring now to the drawings in which like reference numbers represent corresponding parts throughout:

FIGS. 1, 2(a), 2(b), 3(a), and 3(b) are schematic illustrations of quantum well structures comprising graphs of the potential energy function for the structures.

FIG. 4 is a micrograph of a multiple quantum well (MQW) structure.

FIG. 5 is a flowchart describing the process steps for fabrication of a nonpolar, semipolar or polar (Al,Ga,In)N light emitting device according to the preferred embodiment of the present invention.

FIG. 6 is a schematic cross-section of a light emitting device fabricated in FIG. 5 according to the preferred embodiment of the present invention.

FIGS. 7(a) and 7(b) are schematic illustrations of stair quantum well structures according to the present invention comprising graphs of the potential energy function for the structures, wherein the structures have a single step, and the step is on either side of the well.

FIG. 8 is a schematic illustration of a stair quantum well structure according to the present invention comprising graphs of the potential energy function for the structure, wherein the structure has a single step on both sides of the well.

FIGS. 9(a) and 9(b) are schematic illustrations of stair quantum well structures according to the present invention comprising graphs of the potential energy function for the structures, wherein the structures have multiple steps and landings.

FIGS. 10(a) and 10(b) are schematic illustrations of stair quantum well structures according to the present invention comprising graphs of the potential energy function for the structures, wherein the structures have both square and triangular (graded) steps on either side of the well.

FIGS. 11(a), 11(b), 11(c), 11(d), 11(e), 11(f), 11(g) and 11(h) are schematic illustrations of stair quantum well structures according to the present invention comprising graphs of the potential energy function for the structure, wherein the structure have both steps and landings that are flat or inclined on either side of the well.

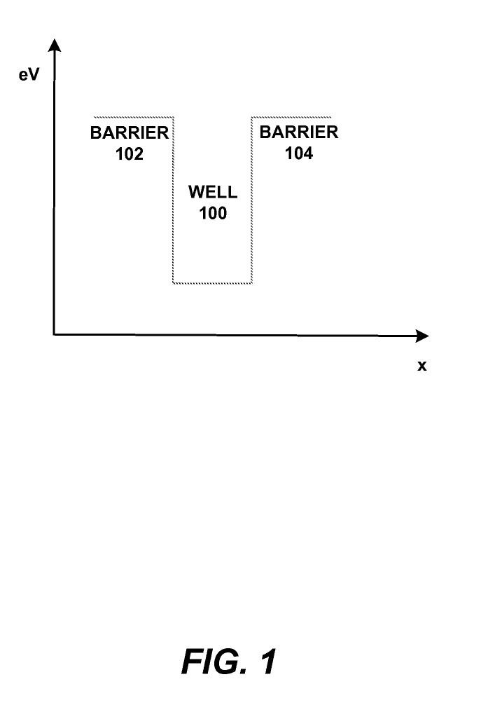

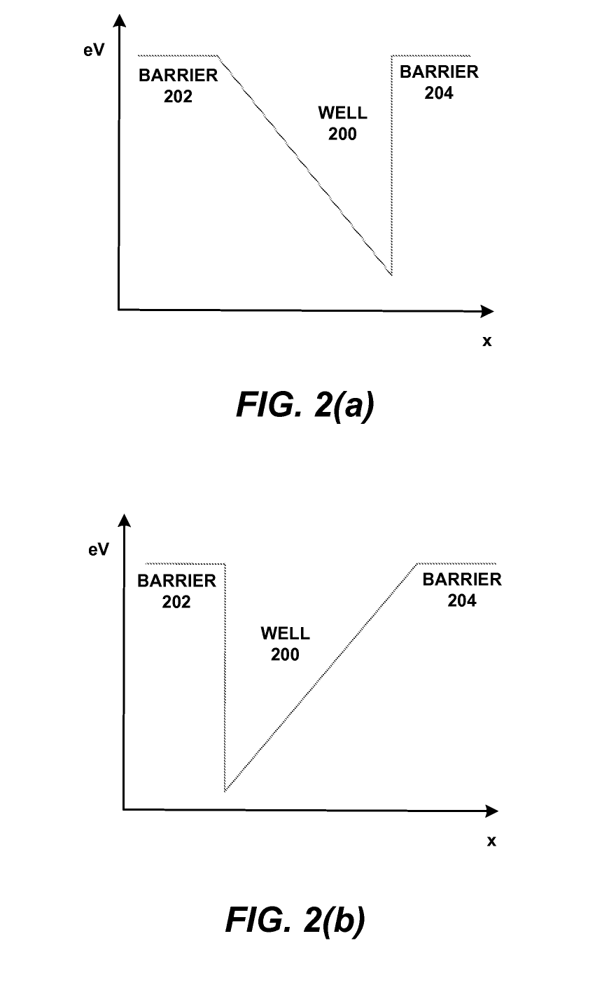

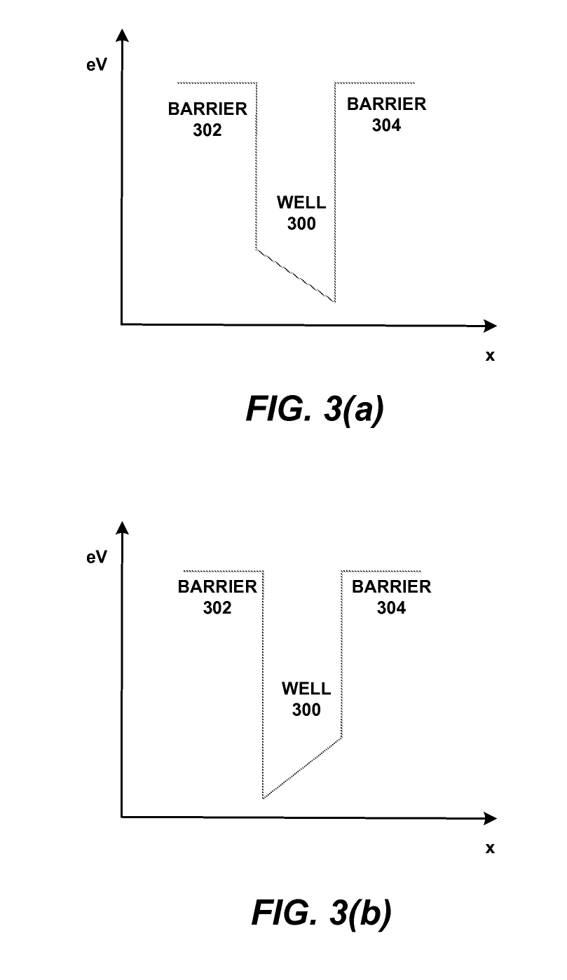

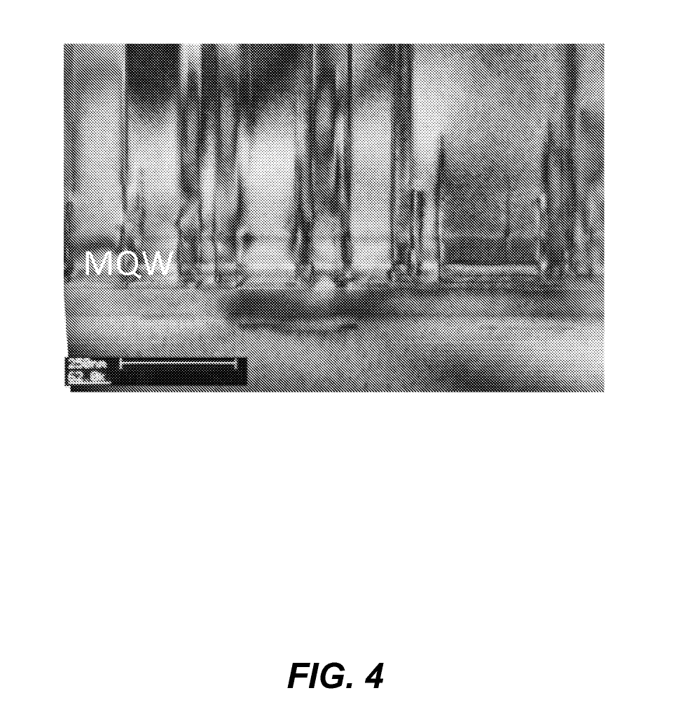

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Device Structure and Fabrication Method

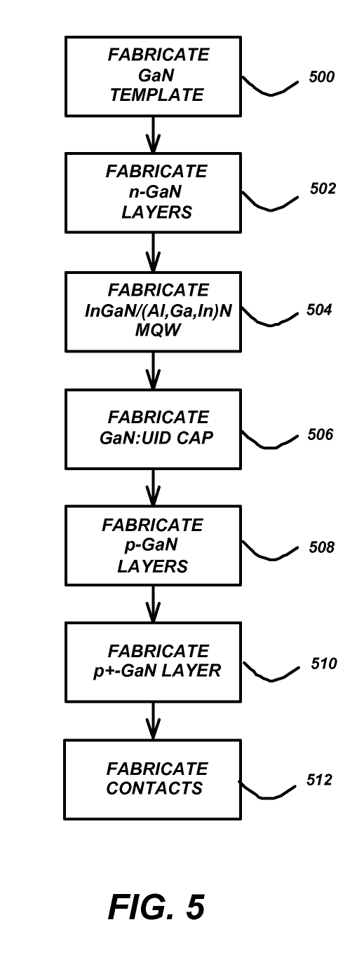

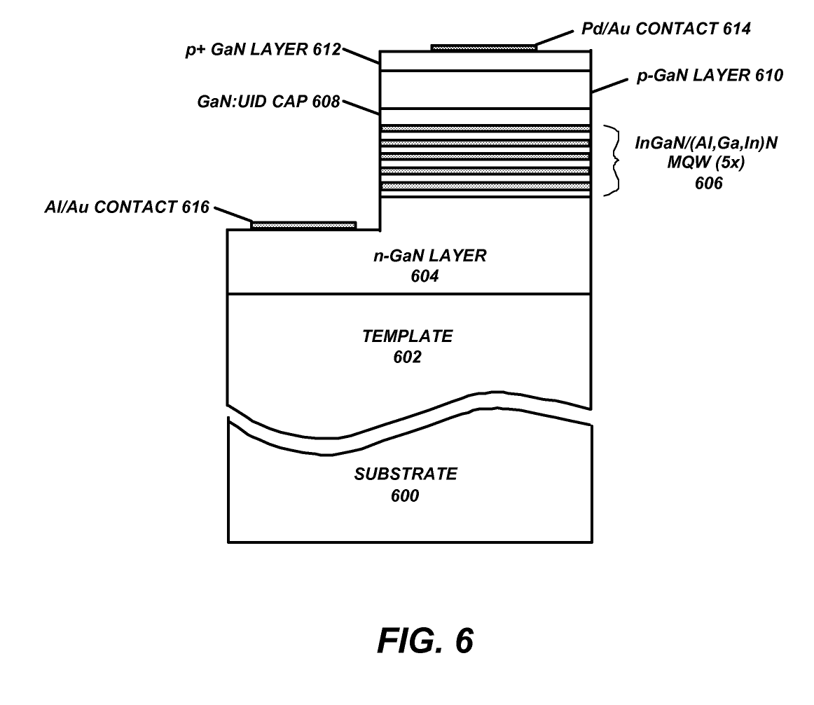

FIG. 5 is a flowchart describing the process steps for fabrication of a nonpolar, semipolar or polar (Al,Ga,In)N light emitting device according to the preferred embodiment of the present invention, while FIG. 6 is a schematic cross-section of a light emitting device fabricated in FIG. 5 according to the preferred embodiment of the present invention.

Block 500 represents the fabrication of a smooth, low-defect-density template on a substrate. For example, this Block may represent the fabrication, on an r-plane sapphire substrate 600, of a GaN template 602.

Block 502 represents the fabrication of an n-GaN base layer 604.

Block 504 represents the fabrication of an active region 606 for the device. In this embodiment, the active region 606 is comprised of a multiple quantum well (MQW) stack comprised of multiple InGaN quantum well layers, wherein each of the InGaN quantum well layers is sandwiched between at least two (Al,Ga,In)N barrier layers.

Block 506 represents the fabrication of an undoped GaN barrier 608 to cap the InGaN/(Al,Ga,In)N MQW structure 606, in order to prevent desorption of In in later steps.

Block 508 represents the fabrication of one or more p-type (Al,Ga)N layers 610 on the undoped GaN barrier 608.

Block 510 represents the fabrication of a heavily doped p⁺-GaN layer 612, which acts as a cap for the structure.

Finally, Block 512 represents the fabrication of a Pd/Au contact 614 and an Al/Au contact 616, as p-GaN and n-GaN contacts, respectively, for the device.

The end result of these process steps is a nonpolar, semipolar or polar (Al,Ga,In)N light emitting device.

Note that this process and the resulting structure are merely exemplary and should not be considered limiting in any way. For example, other embodiments within the scope of this invention may not include these specific steps or layers, and may include other and different steps and layers.

Stair Quantum Wells

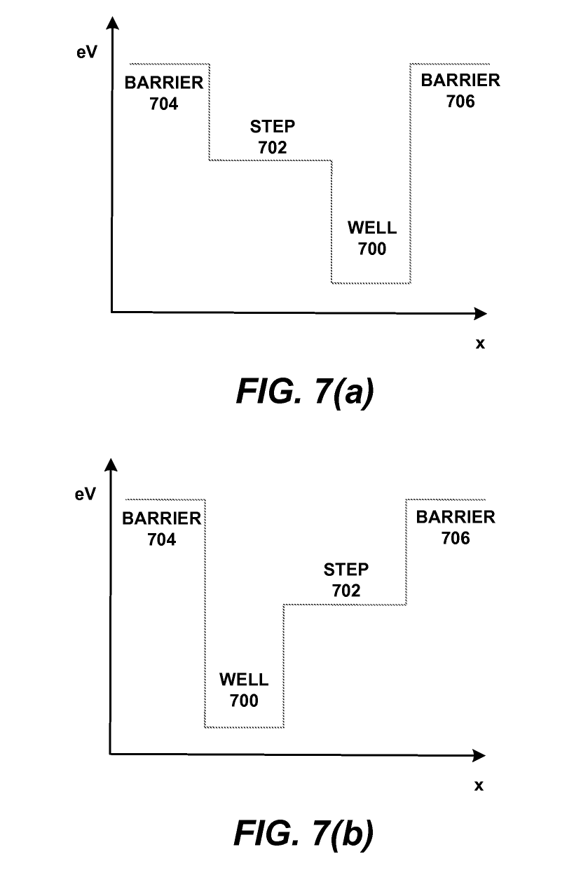

The present invention describes a stair quantum well structure using a number of different variations in the material composition of the layers found in the InGaN/(Al,Ga,In)N MQW structure 606. These variations are schematically illustrated by FIGS. 7(a)-7(b), 8, 9(a)-9(b), 10(a)-10(b) and 11(a)-11(h), which are graphs of the potential energy function for a stair quantum well structure formed by at least one InGaN quantum well layer sandwiched between at least two (Al,Ga,In)N barrier layers in the MQW structure 606.

Generally, the stair quantum well structure has a material composition that creates an energy diagram comprising: (1) at least one primary potential well that is a quantum well bounded by potential barriers, and (2) one or more potential steps between the primary potential well and one or more of the potential barriers. The energy diagram or band structure describes the energy of an electron in the active layer (conduction band), or the energy of holes in the active layer (the valence band).

In the energy diagram, the potential step is different from the primary potential well, and the potential barriers are different from the primary potential well and the potential step. Specifically, the primary potential well, the potential steps and the potential barriers represent one or more abrupt or gradual differences in energy between positions in the energy band structure. As a result, the potential energy increases via the steps from a potential minimum at the bottom of the well to a potential maximum at the top of the barriers bounding the well and steps.

In describing the stair quantum well structure of the present invention, a step may include a step landing or an inclined step, and one or more step walls:
A step landing is created by the material composition remaining substantially consistent for a width of the step landing, which creates a substantially constant potential across the width of the step landing, as reflected by a substantially horizontal line in the energy diagram.
An inclined step is created by a change in the material composition across a width of the inclined step, which creates a change in potential across the width of the inclined step, as reflected by a sloped line in the energy diagram.
One or more step walls are created by an abrupt change in the material composition, which creates an abrupt change in potential at the step wall, as reflected by a substantially vertical line in the energy diagram.

According to one embodiment of the present invention, the stair quantum well structure may have a material composition that creates an energy diagram comprising:

(i) a first one of the potential barriers;

(ii) the potential step, wherein the potential step is a step landing;

(iii) the primary potential well; and

(iv) a second one of the potential barriers.

In addition, where the potential step is a first potential step, and the stair quantum well structure may have a material composition that creates an energy diagram further comprising (v) a second potential step that is different from the primary potential well, wherein the second potential step is an inclined step.

According to another embodiment of the present invention, the stair quantum well structure may have a material composition that creates an energy diagram comprising:

(i) a first one of the potential barriers;

(ii) the potential step, wherein the potential step is an inclined step;

(iii) the primary potential well; and

(iv) a second the potential barriers.

In addition, where the potential step is a first potential step, the stair quantum well structure may have a material composition that creates an energy diagram further comprising (v) a second potential step that is different from the primary potential well, wherein the second potential step is a step landing.

From these general embodiments, the various embodiments shown in FIGS. 7(a)-7(b), 8, 9(a)-9(b), 10(a)-10(b) and 11(a)-11(h) may be derived. However, these embodiments are merely exemplary and are not intended to be exhaustive. Specifically, many variations are possible, including stair quantum well structures with additional and different layers and steps.

FIG. 7(a) and FIG. 7(b) schematically illustrate a single step stair quantum well structure, by means of graphs of the potential energy function. The single step stair quantum well structure comprises a square primary potential well 700 and a potential step 702 comprising a step landing both preceded and followed by step walls. In these figures, the material composition of the primary potential well 700 comprises InₓGa₁₋ₓN, and the material composition of the potential step 702 comprises In_{y}Ga_{1-y}N, where y<x. The primary potential well 700 and the potential step 702 are sandwiched between first and second barriers 704, 706, which are comprised of AlGaN, GaN, AlInGaN or In_{b}Ga_{1-b}N where b<y. Note that the potential step 702 could either be on the left side of the primary potential well 700 (the n-side of the device) or on the right side of the well (the p-side of the device), as shown in FIGS. 7(a) and 7(b), respectively.

FIG. 8 schematically illustrates a multiple step stair quantum well structure, by means of a graph of the potential energy function. The multiple step stair quantum well structure comprises a square primary potential well 800, a first potential step 802a comprising a first step landing both preceded and followed by step walls, and a second potential step 802b comprising a second step landing both preceded and followed by step walls. In this figure, the material composition of the primary potential well 800 comprises InₓGa₁₋ₓN, the material composition of the first potential step 802a comprises In_{y}Ga_{1-y}N, and the material composition of the second potential step 802b comprises In_{z}Ga_{1-z}N, where y<x and z<x. The primary potential well 800 and the potential steps 802, 802b are sandwiched between first and second barriers 804, 806, which are comprised of AlGaN, GaN, AlInGaN or In_{b}Ga_{1-b}N where b<y and b<z. Note that the first potential step 802a is on the left side of the primary potential well 800 (the n-side of the device) and the second potential step 802b is on the right side of the primary potential well 800 (the p-side of the device), respectively.

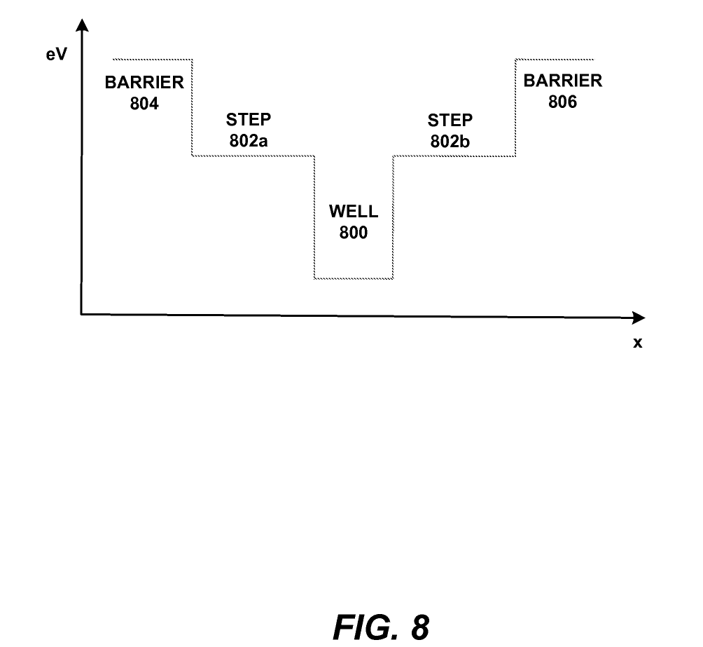

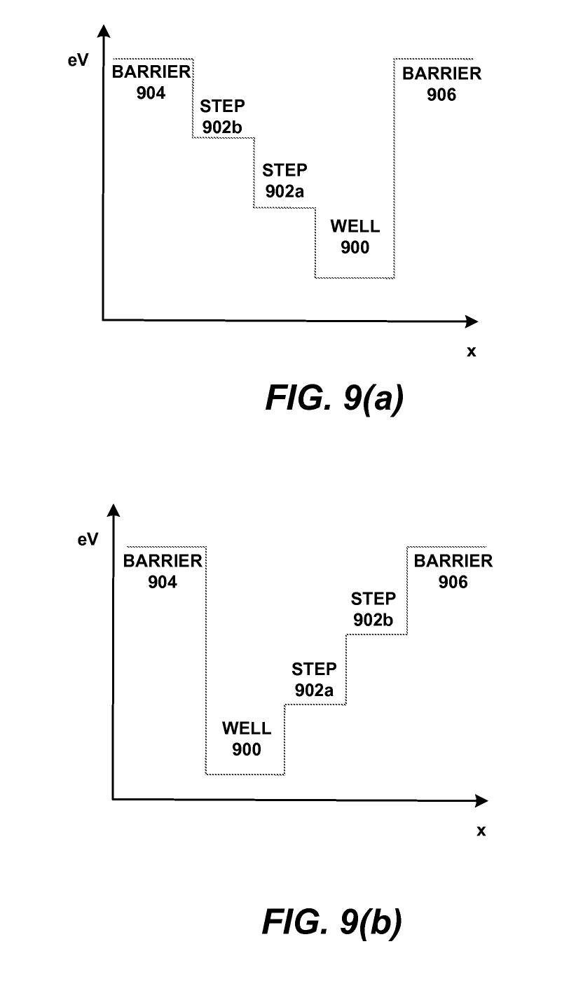

FIGS. 9(a) and 9(b) schematically illustrate a multiple step stair quantum well structure, by means of graphs of the potential energy function. The multiple step stair quantum well structure comprises a square primary potential well 900, a first potential step 902a comprising a first step landing both preceded and followed by step walls, and a second potential step 902b comprising a second step landing both preceded and followed by step walls. In these figures, the material composition of the primary potential well 900 comprises InₓGa₁₋ₓN, the material composition of the first potential step 902a comprises In_{y}Ga_{1-y}N, and the material composition of the second potential step 902b comprises In_{z}Ga_{1-z}N, where z<y<x. The primary potential well 900 and the potential steps 902a, 902b are sandwiched between first and second barriers 904, 906, which are comprised of AlGaN, GaN, AlInGaN or In_{b}Ga_{1-b}N where b<z. Note that the first and second potential steps 902a, 902b are both either on the left side of the primary potential well 900 (the n-side of the device) or the right side of the primary potential well 900 (the p-side of the device), as shown in FIGS. 9(a) and 9(b), respectively. Moreover, the step wall following the first potential step 902a is the same step wall preceding the second potential step 902b.

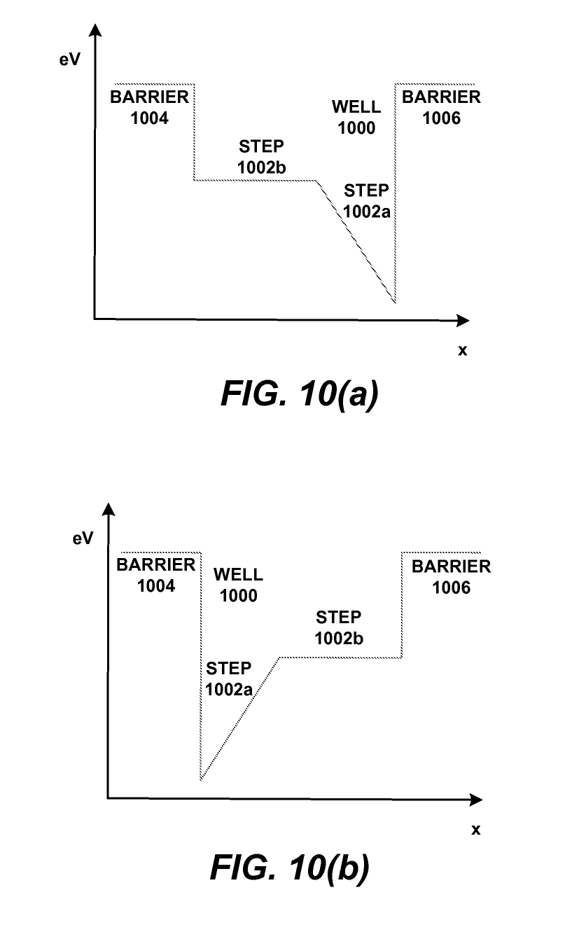

FIGS. 10(a) and 10(b) schematically illustrate a multiple step stair quantum well structure, by means of graphs of the potential energy function. The multiple step stair quantum well structure comprises a primary potential well 1000, a first potential step 1002a comprising a first inclined step, and a second potential step 1002b comprising a second step landing followed by a step wall. In these figures, the material composition of the primary potential well 100 comprises InₓGa₁₋ₓN, the material composition of the first potential step 1002a comprises In_{y}Ga_{1-y}N, and the material composition of the second potential step 1002b comprises In_{z}Ga_{1-z}N, where z<y<x. The primary potential well 1000 and the potential steps 1002a, 1002b are sandwiched between first and second barriers 1004, 1006, which are comprised of AlGaN, GaN, AlInGaN or In_{b}Ga_{1-b}N where b<z. Note that the first and second potential steps 1002a, 1002b are both either on the left side of the primary potential well 1000 (the n-side of the device) or the right side of the primary potential well 1000 (the p-side of the device), as shown in FIGS. 10(a) and 10(b), respectively.

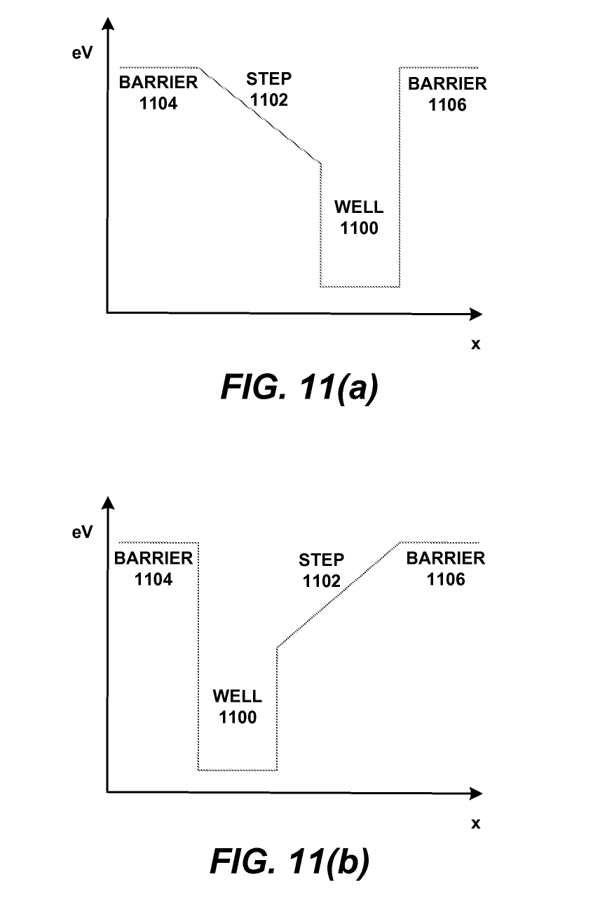

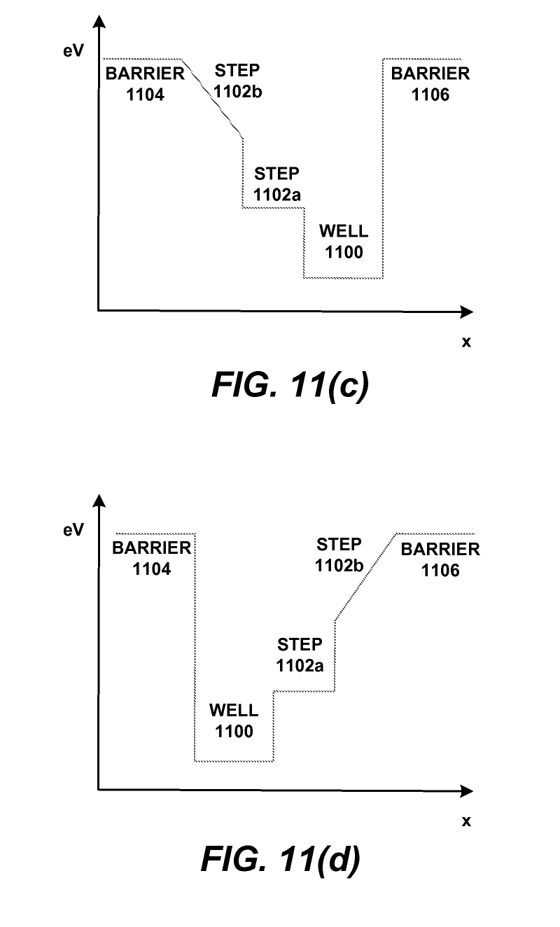

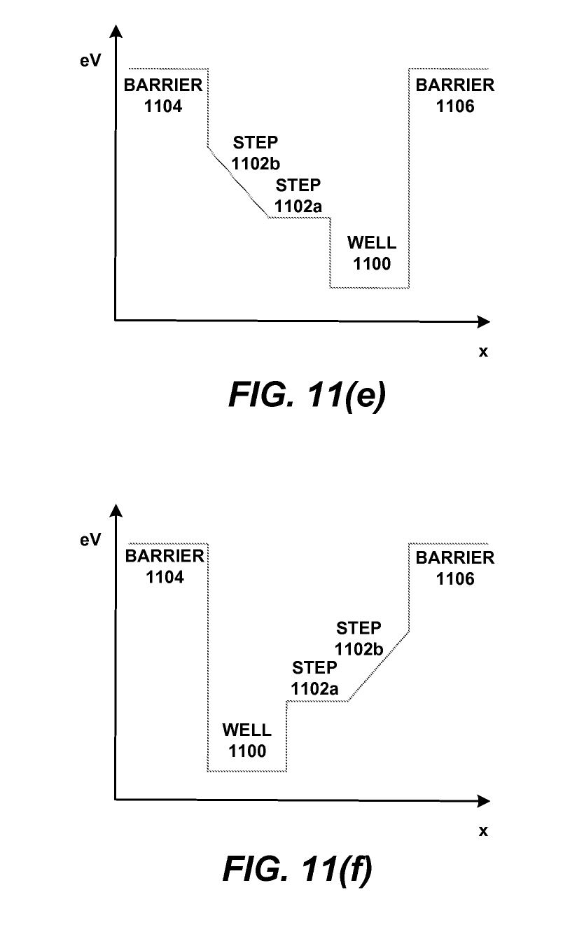

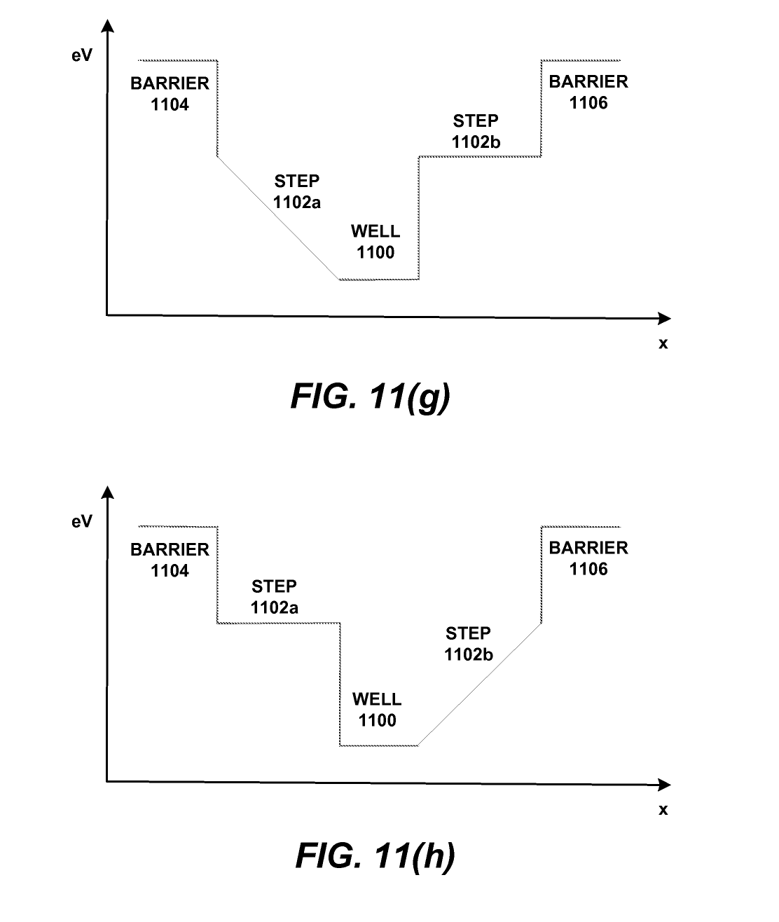

FIGS. 11(a), 11(b), 11(c), 11(d), 11(e), 11(f), 11(g) and 11(h) schematically illustrate alternative single and multiple step stair quantum well structures, by means of graphs of the potential energy function.

In FIGS. 11(a) and 11(b), the single step stair quantum well structure comprises a primary potential well 1100 and a potential step 1002 comprising an inclined step preceded by a step wall. In this figure, the material composition of the primary potential well 1100 comprises InₓGa₁₋ₓN, and the material composition of the potential step 1102 comprises In_{y}Ga_{1-y}N, where y<x. The primary potential well 1100 and the potential step 1102 are sandwiched between first and second barriers 1104, 1106, which are comprised of AlGaN, GaN, AlInGaN or In_{b}Ga_{1-b}N where b<y. Note that the potential step 1102 may be either on the left side of the primary potential well 1100 (the n-side of the device) or the right side of the primary potential well 1100 (the p-side of the device), as shown in FIGS. 11(a) and 11(b), respectively.

FIGS. 11(c) and 11(d) schematically illustrate a multiple step stair quantum well structure, by means of graphs of the potential energy function. The multiple step stair quantum well structure comprises a primary potential well 1100, a first potential step 1102a comprising a first step landing both preceded and followed by step walls, and a second potential step 1102b comprising a second inclined step preceded by a step wall. In these figures, the material composition of the primary potential well 1100 comprises InₓGa₁₋ₓN, the material composition of the first potential step 1102a comprises In_{y}Ga_{1-y}N, and the material composition of the second potential step 1102b comprises In_{z}Ga_{1-z}N, where z<y<x. The primary potential well 1100 and the potential steps 1102a, 1102b are sandwiched between first and second barriers 1104, 1106, which are comprised of AlGaN, GaN, AlInGaN or In_{b}Ga_{1-b}N where b<z. Note that the first and second potential steps 1102a, 1102b are both either on the left side of the primary potential well 1100 (the n-side of the device) or the right side of the primary potential well 1100 (the p-side of the device), as shown in FIGS. 11(c) and (d), respectively. Moreover, the step wall following the first potential step 1102a is the same step wall preceding the second potential step 1102b.

FIGS. 11(e) and 11(f) schematically illustrate a multiple step stair quantum well structure, by means of graphs of the potential energy function. The multiple step stair quantum well structure comprises a primary potential well 1100, a first potential step 1102a comprising a first step landing preceded by a step wall, and a second potential step 1102b comprising a second inclined step followed by a step wall. In these figures, the material composition of the primary potential well 1100 comprises InₓGa₁₋ₓN, the material composition of the first potential step 1102a comprises In_{y}Ga_{1-y}N, and the material composition of the second potential step 1102b comprises In_{z}Ga_{1-z}N, where z<y<x. The primary potential well 1100 and the potential steps 1102a, 1102b are sandwiched between first and second barriers 1104, 1106, which are comprised of AlGaN, GaN, AlInGaN or In_{b}Ga_{1-b}N where b<z. Note that the first and second potential steps 1102a, 1102b are both either on the left side of the primary potential well 1100 (the n-side of the device) or the right side of the primary potential well 1100 (the p-side of the device), as shown in FIGS. 11(e) and (d), respectively.

FIGS. 11(g) and 11(h) schematically illustrate a multiple step stair quantum well structure, by means of graphs of the potential energy function. In FIG. 11(g), the multiple step stair quantum well structure comprises a primary potential well 1100, a first potential step 1102a comprising a first step landing, and a second potential step 1102b comprising a second inclined step. In FIG. 11(h), the multiple step stair quantum well structure comprises a primary potential well 1100, a first potential step 1102a comprising a first inclined step, and a second potential step 1102b comprising a second step landing. In these figures, the material composition of the primary potential well 1100 comprises InₓGa₁₋ₓN, the material composition of the first potential step 1102a comprises In_{y}Ga_{1-y}N, and the material composition of the second potential step 1102b comprises In_{z}Ga_{1-z}N, where y<x and z<x. The primary potential well 1100 and the potential steps 1102a, 1102b are sandwiched between first and second barrier layers 1104, 1106, which are comprised of AlGaN, GaN, AlInGaN or In_{b}Ga_{1-b}N where b<y and b<z. Note that the first and second potential steps 1102a, 1102b are on opposite sides of the primary potential well 1100, as shown in FIGS. 11(g) and (h), respectively.

Advantages and Improvements

The present invention has the following advantages as compared to the prior art:

1. The use of a stair quantum well structure with a thin primary well and one or more steps allows for strain relief, because the quantum well structure is essentially graded from the primary well to the barrier using the step.

2. The use of the step also reduces quantum confinement, resulting in the lowering of the ground state energy level. This allows longer wavelength emission from a lower In composition in the primary well.

The best way of practicing this invention would be to use the stair quantum well structure for a blue-green-yellow (Al,Ga,In)N based light emitting device, as noted above. The impact of the stair quantum well structure is higher for quantum wells with high In composition.

Using this invention, an output power of 0.7 mW was achieved for an LED using the stair quantum well design, as compared to 0.05 mW for an LED using a conventional square quantum well design. Both of these LEDs emitted at the same wavelength.

Possible Modifications

There may be various embodiments of the present invention. For example, the following variations are possible:

1. The wells may be square or triangular (graded) wells. The wells may have other shapes as well. The grading of the wells may be linear or non-linear.

2. The steps may be square or triangular (graded) steps. The steps may have other shapes as well. The grading of the steps may be linear or non-linear.

3. This invention can be applied to nonpolar, semipolar or polar light emitting devices.

4. This invention can be applied to light emitting structures containing AlInGaN barriers within the active region.

5. The invention can be applied to light emitting structures containing InGaN as the primary quantum well.

6. The light emitting device can be a laser, a light-emitting diode, etc.

7. This invention can be applied for any wavelength ranging from the ultraviolet (UV) to yellow spectral range.

Nomenclature

The terms (Al,Ga,In)N, III-nitride, Group III-nitride, nitride, Al_{(1-x-y)}GaₓIn_{y}N where 0<x<1 and 0<y<1, or AlInGaN, as used herein are intended to be broadly construed to include respective nitrides of the single species, Al, Ga and In, as well as binary, ternary and quaternary compositions of such Group III metal species. Accordingly, the term (Al,Ga,In)N comprehends the compounds AN, GaN, and InN, as well as the ternary compounds AlGaN, GaInN, and AlInN, and the quaternary compound AlGaInN, as species included in such nomenclature. Accordingly, it will be appreciated that the discussion of the invention hereinafter in reference to specific (Al,Ga,In)N materials, such as GaN or InGaN, is applicable to the formation of various other species of these (Al,Ga,In)N materials. Further, (Al,Ga,In)N materials within the scope of the invention may further include minor quantities of dopants and/or other impurity or inclusional materials.

(Al,Ga,In)N optoelectronic and electronic devices are typically grown on c-plane sapphire substrates, SiC substrates or bulk (Al,Ga,In)N substrates. In each instance, the devices are usually grown along their polar (0001) c-axis orientation, i.e., a c-plane direction.

However, conventional polar (Al,Ga,In)N based devices suffer from undesirable quantum-confined Stark effect (QCSE), due to the existence of strong piezoelectric and spontaneous polarizations. For example, GaN and its alloys are the most stable in a hexagonal würtzite crystal structure, in which the structure is described by two (or three) equivalent basal plane axes that are rotated 120° with respect to each other (the a-axis), all of which are perpendicular to a unique c-axis. Group III atoms, such as Ga, and N atoms occupy alternating c-planes along the crystal's c-axis. The symmetry elements included in the würtzite structure dictate that (Al,Ga,In)N devices possess a bulk spontaneous polarization along this c-axis, and the würtzite structure exhibits piezoelectric polarization, which give rise to restricted carrier recombination efficiency, reduced oscillator strength, and red-shifted emission.

One approach to eliminating the spontaneous and piezoelectric polarization effects in (Al,Ga,In)N devices is to grow the devices on nonpolar planes of the crystal, which are orthogonal to the c-plane of the crystal. For example, with regard to GaN, such planes contain equal numbers of Ga and N atoms, and are charge-neutral. Furthermore, subsequent nonpolar layers are crystallographically equivalent to one another, so the crystal will not be polarized along the growth direction. Two such families of symmetry-equivalent nonpolar planes in GaN are the {11-20} family, known collectively as a-planes, and the {1-100} family, known collectively as m-planes.

Another approach to reducing or possibly eliminating the polarization effects in GaN optoelectronic devices is to grow the devices on semipolar planes of the crystal. The term semipolar planes can be used to refer to a wide variety of planes that possess two nonzero h, i, or k Miller indices, and a nonzero 1 Miller index. Some examples of semipolar planes in the würtzite crystal structure include, but are not limited to, {10-12}, {20-21}, and {10-14}. The crystal's polarization vector lies neither within such planes or normal to such planes, but rather lies at some angle inclined relative to the plane's surface normal.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A light emitting device, comprising:
an (Al,Ga,In)N based active region including at least one stair quantum well structure formed by at least one (Al,Ga,In)N based quantum well layer sandwiched between at least first and second (Al,Ga,In)N based barrier layers;
wherein the stair quantum well structure has a material composition that creates an energy diagram comprising:
(1) at least one primary potential well that is a quantum well bounded by potential barriers, and
(2) at least one potential step between the primary potential well and one or more of the potential barriers.

2. The device of claim 1, wherein the potential step is different from the primary potential well, and the potential barriers are different from the primary potential well and the potential step.

3. The device of claim 1, wherein the potential step is a step landing created by the material composition remaining substantially consistent for a width of the step landing, which creates a substantially constant potential across the width of the step landing, as reflected by a substantially horizontal line in the energy diagram.

4. The device of claim 1, wherein the potential step includes one or more step walls created by an abrupt change in the material composition, which creates an abrupt change in potential at the step wall, as reflected by a substantially vertical line in the energy diagram.

5. The device of claim 1, wherein the potential step is an inclined step created by a change in the material composition across a width of the inclined step, which creates a change in potential across the width of the inclined step, as reflected by a sloped line in the energy diagram.

6. The device of claim 1, wherein the stair quantum well structure has a material composition that creates an energy diagram comprising:
(i) a first one of the potential barriers;
(ii) the potential step, wherein the potential step is a step landing;
(iii) the primary potential well; and
(iv) a second one of the potential barriers.

7. The device of claim 6, wherein the potential step is a first potential step, and the stair quantum well structure has a material composition that creates an energy diagram further comprising:
(v) a second potential step that is different from the primary potential well, wherein the second potential step is an inclined step.

8. The device of claim 1, wherein the stair quantum well structure has a material composition that creates an energy diagram comprising:
(i) a first one of the potential barriers;
(ii) the potential step, wherein the potential step is an inclined step;
(iii) the primary potential well; and
(iv) a second the potential barriers.

9. The device of claim 8, wherein the potential step is a first potential step, and the stair quantum well structure has a material composition that creates an energy diagram further comprising:
(v) a second potential step that is different from the primary potential well, wherein the second potential step is a step landing.

10. The device of claim 1, wherein the material composition of the primary potential well is InₓGa₁₋ₓN, and the material composition of the step is In_{y}Ga_{1-y}N, where the potential step is a step landing and y<x.

11. The device of claim 1, wherein the material composition of the primary potential well is InₓGa₁₋ₓN, the material composition of the step is In_{y}Ga_{1-y}N, where the step is a inclined step and y<x.

12. The device of claim 1, wherein the potential step is a first potential step, and the stair quantum well structure has a material composition that creates an energy diagram further comprising:
(3) a second potential step that is different from the primary potential well.

13. The device of claim 12, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is a step landing, the second potential step is a step landing, and y<x and z<x.

14. The device of claim 12, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is a step landing, the second potential step is a step landing, and z<y<x.

15. The device of claim 12, wherein the material composition of the primary potential well is InₓGa_{1-y}N, the material composition of the first potential step is In_{y}Ga_{1-y}N, and the material composition of the second potential step is In_{z}Ga_{1-z}N, where the first potential step is a step landing, the second potential step is an inclined step, and y<x and z<x.

16. The device of claim 12, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is a step landing, the second potential step is an inclined step, and z<y<x.

17. The device of claim 12, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is an inclined step, the second potential step is a step landing, and y<x and z<x.

18. The device of claim 12, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is an inclined step, the second potential step is a step landing, and z<y<x.

19. The device of claim 1, wherein the material composition comprises a polar, nonpolar or semipolar (Al,Ga,In)N based material composition.

20. The device of claim 1, wherein the potential step is either on an n-side of the device or on a p-side of the device.

21. The device of claim 1, further comprising a plurality of potential steps on both sides of the primary potential well.

22. The device of claim 1, further comprising a plurality of potential steps on either side of the primary potential well.

23. A method for fabricating a light emitting device, comprising:
fabricating an (Al,Ga,In)N based active region including at least one stair quantum well structure formed by at least one (Al,Ga,In)N based quantum well layer sandwiched between at least first and second (Al,Ga,In)N based barrier layers;
wherein the stair quantum well structure has a material composition that creates an energy diagram comprising:
(1) at least one primary potential well that is a quantum well bounded by potential barriers, and
(2) one or more potential steps between the primary potential well and one or more of the potential barriers.

24. The method of claim 23, wherein the potential step is different from the primary potential well, and the potential barriers are different from the primary potential well and the potential step.

25. The method of claim 23, wherein the potential step is a step landing created by the material composition remaining substantially consistent for a width of the step landing, which creates a substantially constant potential across the width of the step landing, as reflected by a substantially horizontal line in the energy diagram.

26. The method of claim 23, wherein the potential step includes one or more step walls created by an abrupt change in the material composition, which creates an abrupt change in potential at the step wall, as reflected by a substantially vertical line in the energy diagram.

27. The method of claim 23, wherein the potential step is an inclined step created by a change in the material composition across a width of the inclined step, which creates a change in potential across the width of the inclined step, as reflected by a sloped line in the energy diagram.

28. The method of claim 23, wherein the stair quantum well structure has a material composition that creates an energy diagram comprising:
(i) a first one of the potential barriers;
(ii) the potential step, wherein the potential step is a step landing;
(iii) the primary potential well; and
(iv) a second one of the potential barriers.

29. The method of claim 28, wherein the potential step is a first potential step, and the stair quantum well structure has a material composition that creates an energy diagram further comprising:
(v) a second potential step that is different from the primary potential well, wherein the second potential step is an inclined step.

30. The method of claim 23, wherein the stair quantum well structure has a material composition that creates an energy diagram comprising:
(i) a first one of the potential barriers;
(ii) the potential step, wherein the potential step is an inclined step;
(iii) the primary potential well; and
(iv) a second the potential barriers.

31. The method of claim 30, wherein the potential step is a first potential step, and the stair quantum well structure has a material composition that creates an energy diagram further comprising:
(v) a second potential step that is different from the primary potential well, wherein the second potential step is a step landing.

32. The method of claim 23, wherein the material composition of the primary potential well is InₓGa₁₋ₓN, and the material composition of the step is In_{y}Ga_{1-y}N, where the potential step is a step landing and y<x.

33. The method of claim 23, wherein the material composition of the primary potential well is InₓGa₁₋ₓN, the material composition of the step is In_{y}Ga_{1-y}N, where the step is a inclined step and y<x.

34. The method of claim 23, wherein the potential step is a first potential step, and the stair quantum well structure has a material composition that creates an energy diagram further comprising:
(3) a second potential step that is different from the primary potential well.

35. The method of claim 34, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is a step landing, the second potential step is a step landing, and y<x and z<x.

36. The method of claim 34, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is a step landing, the second potential step is a step landing, and z<y<x.

37. The method of claim 34, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is a step landing, the second potential step is an inclined step, and y<x and z<x.

38. The method of claim 34, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is a step landing, the second potential step is an inclined step, and z<y<x.

39. The method of claim 34, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is an inclined step, the second potential step is a step landing, and y<x and z<x.

40. The method of claim 34, wherein the material composition of the primary potential well is InₓGa₁₋ₓN, the material composition of the first potential step is In_{y}Ga_{1-y}N, and the material composition of the second potential step is In_{z}Ga_{1-z}N, where the first potential step is an inclined step, the second potential step is a step landing, and z<y<x.

41. The method of claim 23, wherein the material composition comprises a polar, nonpolar or semipolar (Al,Ga,In)N based material composition.

42. The method of claim 23, wherein the potential step is either on an n-side of the device or on a p-side of the device.

43. The method of claim 23, further comprising a plurality of potential steps on both sides of the primary potential well.

44. The method of claim 23, further comprising a plurality of potential steps on either side of the primary potential well.

45. A device fabricated using the method of claim 23.
